(19) United States
(12) Patent Application Publication
(10) Pub. No.: US 2025/0133886 A1
(43) Pub. Date: Apr. 24, 2025

(54) SYMMETRICAL LEAD FRAME STRUCTURE FOR TWO-PIN LED PACKAGE

(71) Applicant: CreeLED, Inc., Durham, NC (US)

(72) Inventors: Robert David Schmidt, Wake Forest, NC (US); Joseph M. Favale, JR., Cary, NC (US)

(21) Appl. No.: 18/493,039

(22) Filed: Oct. 24, 2023

(51) Int. Cl. H01L 33/62; H01L 33/52; H01L 33/60

(52) U.S. Cl. CPC H10H 20/857; H10H 20/852; H10H 20/856; H10H 20/0364

(57) ABSTRACT

Solid-state lighting devices, and more particularly, symmetrical lead frame structures for two-pin light emitting diode (LED) packages and methods for making the same are disclosed. The symmetrical lead frame structure can include a pair of leads that include symmetrical split cup portions that collectively, when placed next to each other, form a cup, across which an LED flip-chip can be placed. Each of the leads can be a respective electrode powering the LED flip-chip, which together with the symmetrical structure, provides a more even light emission profile and far-field pattern. A molded lens can be formed around the lead frame to protect the chip, as well as maintain a gap between the pair of leads of the lead frame structure. In some embodiments, a fill material can be added in the gap between the pair of leads.

### FIELD OF THE DISCLOSURE

The present disclosure relates to a solid-state lighting device, and more particularly to a symmetrical lead frame structure for a two-pin light emitting diode (LED) package.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination and automotive applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, aluminum nitride, gallium arsenide-based materials, and/or from organic semiconductor materials. Photons generated by the active region are initiated in all directions.

The art continues to seek improved LEDs and solid-state lighting devices having desirable illumination characteristics capable of overcoming challenges associated with traditional lighting devices.

### SUMMARY

The present disclosure relates to a solid-state lighting device, and more particularly to a symmetrical lead frame structure for a two-pin light emitting diode (LED) package and a method for making the same. The symmetrical lead frame structure can include a pair of leads that include symmetrical split cup portions that collectively, when placed next to each other, form a cup, across which an LED flip-chip can be placed. Each of the leads can be a respective electrode powering the LED flip-chip, which together with the symmetrical structure, provides a more even light emission profile and far-field pattern. A molded lens can be formed around the lead frame to protect the chip, as well as maintain a gap between the pair of leads of the lead frame structure. In some embodiments, a fill material can be added in the gap between the pair of leads

In an embodiment, an LED package can include a lead frame structure, comprising a pair of leads that each comprise a respective split cup portion on a top portion of the lead, such that a cup is formed by split cup portions of the pair of leads when the pair of leads are adjacent to each other, wherein the cup comprises a gap between the split cup portions and an LED device mounted in the cup across the gap, wherein the LED device is electrically coupled to both split cup portions.

In an embodiment, the LED package can also include a molded lens that encapsulates a top portion of each lead of the pair of leads, the cup, and the LED device.

In an embodiment the LED device is thermally coupled to both split cup portions.

In an embodiment the split cup portions of the pair of leads that form the cup are symmetrical across a line of symmetry formed by the gap.

In an embodiment the cup is circular.

In an embodiment the cup is oval.

In an embodiment a top portion of the cup forms an oval, and a bottom surface of the cup is circular.

In an embodiment the split cup portions comprise respective bottom surfaces on which the LED device is mounted.

In an embodiment material of the molded lens is in the gap between the split cup portions.

In an embodiment top portions of the leads that are encapsulated in the molded lens are symmetrical.

In an embodiment the LED package further includes a fill material in the gap between the split cup portions, wherein the fill material is an electrically insulating material.

In an embodiment a top surface of the fill material has a reflective coating applied thereonto.

In an embodiment surfaces of the split cup portions of the pair of leads have a reflective coating applied thereonto.

In an embodiment side walls of the split cup portions comprise a surface that is angled with respect to a vertical axis of the pair of leads.

In an embodiment sidewalls of the split cup portions comprise a vertical wall portion and a wall portion that is angled with respect to the vertical wall portion.

In an embodiment the LED device is a flip-chip.

In an embodiment the pair of leads are aligned along an axis, and wherein the LED device is mounted along the axis.

In an embodiment, an LED package includes a lead frame structure comprising a pair of leads, wherein each of the leads comprise symmetrical split cup portions on a top portion of the lead, such that a cup is formed by the split cup portions of the pair of leads when the pair of leads are adjacent to each other, wherein the cup comprises a bottom surface and a gap between the split cup portions. The LED package can also include an LED device mounted in on the bottom surface of the split cup portions, wherein a first end of the LED device is mounted on a first bottom surface of a first split cup portion and a second end of the LED device is mounted on a second bottom surface of a second split cup portion and a molded lens that encapsulates a top portion of each leads of the pair of leads, the cup, and the LED device.

In an embodiment, material of the molded lens is in the gap between the split cup portions.

In an embodiment, the LED package further includes a fill material in the gap between the split cup portions, wherein the fill material is an electrical insulator.

In an embodiment, the pair of leads are aligned along an axis, and wherein the LED device is mounted along the axis.

In an embodiment a method for forming an LED package includes mounting an LED device in a cup formed by symmetrical split cup portions on top portions of a pair of leads of a lead frame structure, wherein the LED device is mounted across a gap between the split cup portions, wherein bottom portions of the pair of leads are connected by a connecting portion. The method also includes encapsulating a top portion of each lead of the pair of leads, the cup, and the LED device in a molded lens and removing the connected portion connecting the bottom portions of the pair of leads.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is an exemplary isometric view of a lead frame of a light emitting diode (LED) package according to one or more embodiments of the present disclosure.

FIG. 2 is a top-down view of the lead frame of the LED package of FIG. 1 according to one or more embodiments of the present disclosure.

FIG. 3 is a side view of the lead frame of the LED package of FIG. 1 according to one or more embodiments of the present disclosure.

FIG. 4 is a top-down view of the LED package with an LED device placed across a gap between the split cup portions of the lead frame according to one or more embodiments of the present disclosure.

FIG. 5 is a side view of the lead frame with a fill material in the gap between the lead frames according to one or more embodiments of the present disclosure.

FIG. 6 is a cross-sectional view of an LED device mounted across a gap between the split cup portions of the lead frame with a first side wall configuration according to one or more embodiments of the present disclosure.

FIG. 7 is a cross-sectional view of an LED device mounted across a gap between the split cup portions of the lead frame with a second side wall configuration according to one or more embodiments of the present disclosure.

FIG. 8 is a top-down view of the lead frame of an LED package similar to that of FIG. 2 but with an oval cup according to one or more embodiments of the present disclosure.

FIG. 9 is a side view of the LED package with a molded lens according to one or more embodiments of the present disclosure.

FIG. 10 is a flow chart of a method for making an LED package with a symmetrical lead frame structure according to one or more embodiments of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to a solid-state lighting device, and more particularly to a symmetrical lead frame structure for a two-pin light emitting diode (LED) package and a method for making the same. The symmetrical lead frame structure can include a pair of leads that include symmetrical split cup portions that collectively, when placed next to each other, form a cup, across which an LED flip-chip can be placed. The pair of leads forming the symmetrical lead frame structure may collectively be called the “lead frame” or “lead frame structure” herein. Each of the leads can be a respective electrode powering the LED flip-chip, which together with the symmetrical structure, provides a more even light emission profile and far-field pattern. A molded lens can be formed around the lead frame to protect the chip, as well as maintain a gap between the lead frame. In some embodiments, a fill material can be added in the gap between the lead frame.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group III-V systems such as gallium phosphide (GaP), gallium arsenide (GaAs), and related compounds.

The active LED structure may be grown on a growth substrate that can include many materials, such as sapphire, SiC, silicon, aluminum nitride (AlN), and GaN. Sapphire is another common substrate for Group III nitrides and also has certain advantages, including being lower cost, having established manufacturing processes, and having good light-transmissive optical properties, among other related substrates.

Different embodiments of the active LED structure can emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive”material may be configured to transmit at least 50% of emitted radiation of a desired wavelength.

The present disclosure can be useful for LED chips having a variety of geometries, such as lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support member, such as a lead frame structure. Light-altering materials may be arranged within LED packages to reflect or otherwise redirect light from the one or more LED chips in a desired emission direction or pattern.

In certain embodiments, aspects of the present disclosure relate LED packages with lead frame structures that are at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. An encapsulant material, such as silicone or epoxy, may fill the recess to encapsulate the one or more LED chips.

As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

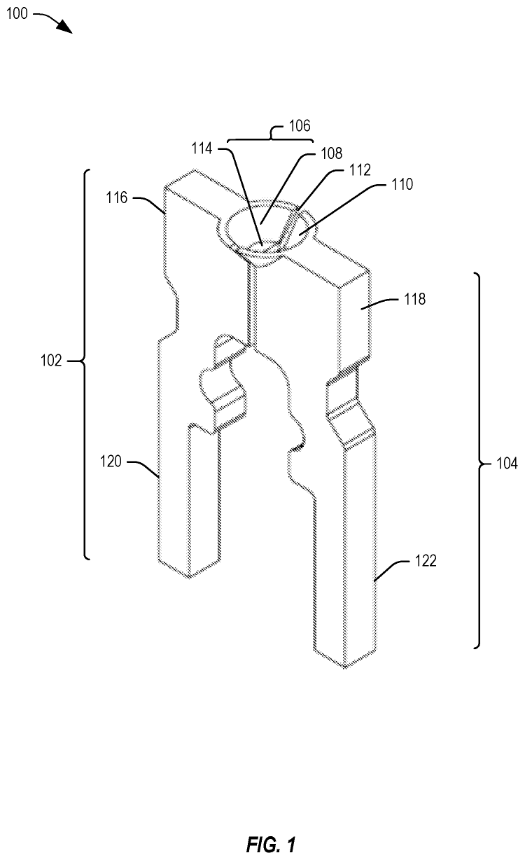

FIG. 1 illustrates an exemplary isometric view of a pair of electrodes or leads 102 and 104 that collectively form the lead frame 100 according to one or more embodiments of the present disclosure.

Traditionally, two-pin LED packages are asymmetrical, with one lead including a cup in which the LED device is mounted, and an LED chip placed inside the cup fixed to the bottom surface of the cup. In certain packages, the LED chip has a vertical geometry having only one of the anode or cathode on a top surface and the other on the bottom surface, with the bottom conductive surface making electrical contact with the cup, with the second lead being electrically attached to a top surface of the vertical LED chip via a wire. In other packages, the LED chip has a lateral geometry with anode and cathode both on a top surface of the chip, with the bottom surface being attached to the cup, and the electrical contacts with the cup and lead attached to a top surface of the lateral LED chip via wires. The placement of the wires, and the asymmetrical leads, cause asymmetries in the light emission profile and/or far field pattern (FFP) of the LED package, especially once the molded lens was placed over the leads and LED device.

In the present disclosure however, the two-pin design has been modified so that the leads are symmetrical, with each lead including a portion of the cup (a split cup portion) such that when the leads are placed adjacent to each other, a cup is formed, with a gap between the leads to avoid electrical contact with each other. A horizontal geometry LED device, such as a flip-chip, can be placed across the gap, in contact with each lead, with each lead being an electrode for the LED device.

Since the leads 102 and 104 are symmetrical in the embodiment disclosed herein, and there is no wire bond on top of the chip as in a traditional two-pin LED package, the FFP is more even. An additional advantage of this design, is that the wire bond in the traditional two-pin LED package can be a failure point of the traditional two-pin LED package. By using a flip chip, which the symmetrical lead frame structure enables, this failure point is overcome. Additionally, since the LED device is coupled to both leads, there can be greater thermal dissipation and distribution, resulting in lower operating temperatures, and extended LED device life. The fabrication costs can be also be reduced due to not having to go through the process of forming the wire bonds to the top of the vertical geometry LED device.

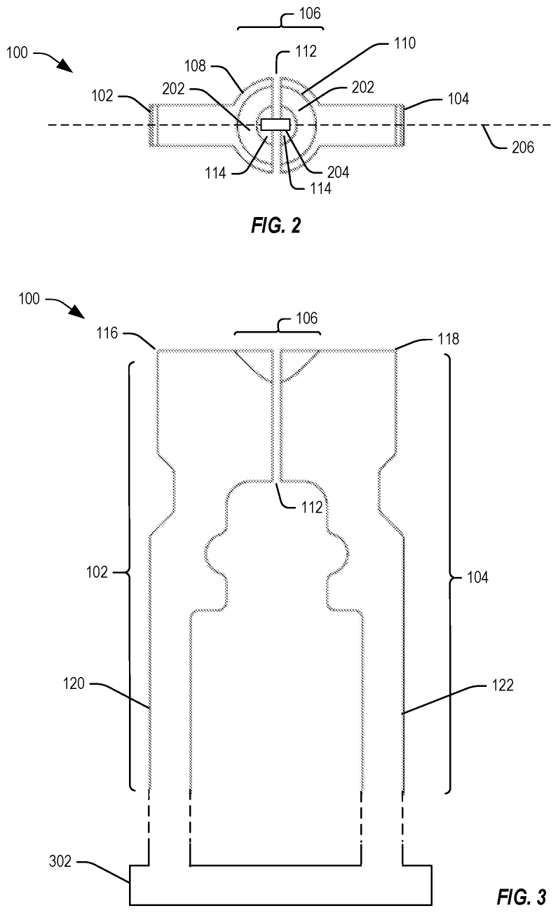

In the lead frame structure 100, each of the leads 102 and 104 include split cup portions 108 and 110 that collectively, when placed side by side, form a cup 106. The cup 106 has sidewalls (shown in more detail in FIGS. 2, and 6-7). The cup 106 also has a bottom 114 on which the LED device can be placed (see FIGS. 2, 4, and 6-7 for more details).

A gap 112 can be maintained between the leads 102 and 104, and the split cup portions 108 and 110 in order to avoid any short circuits, as the leads 102 and 104 act as anode/cathode for the LED device mounted in the cup 106. In certain embodiments, the gap 112 defines a line of symmetry for the cup 106. Whereas each of the split cup portions 108 and 110 are transversely symmetrical across the gap.

The leads 102 and 104 can also include respective lower portions 120 and 122, and top portions 116 and 118. The bottom portions 120 and 122 can be exposed when the molded lens is formed over the LED package (see FIG. 8 for more details), while the upper portions 116 and 118 will be encased in the molded lens. In an embodiment, the top portions 116 and 118 can be symmetrical. Likewise, the bottom portions 120 and 122 can also be symmetrical.

FIG. 2 illustrates a top-down view of the lead frame 100 of the LED package of FIG. 1 according to one or more embodiments of the present disclosure.

In the embodiment shown in FIG. 2, an LED device 204 is mounted on the bottom surfaces 114 of each split cup portions 108 and 110 across the gap 112. The LED device 204 can be a horizontal geometry LED chip such as a flip-chip, where each of leads 102 and 104 is an electrode (e.g., anode or cathode) powering the LED device 204.

In an embodiment, the LED device 204 can be aligned and mounted on the bottom surfaces 114 along an axis 206 that bisects each lead 102 and 104. In other embodiments, the LED device 204 can be arranged at different angles, but the aligned angle can be advantageous due to the light emission profile being symmetrical with respect to the leads 102 and 104.

The LED device 204 can be rectangular, circular, or any other shape as long as at least one portion is mounted on the bottom surface 114 of lead 102 and another portion is mounted on the bottom surface 114 of lead 104.

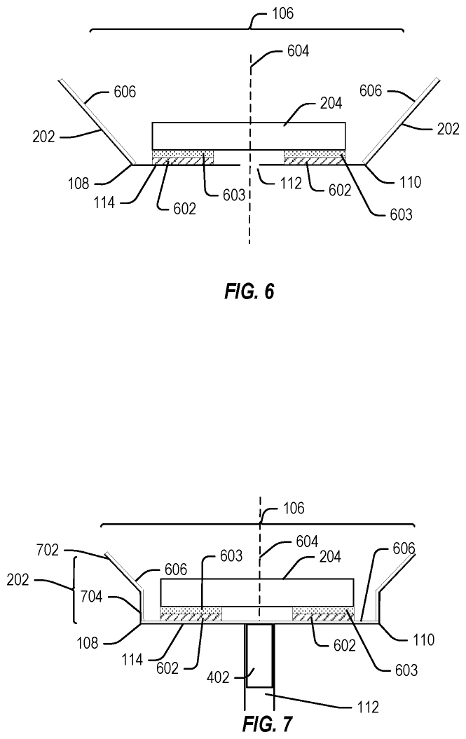

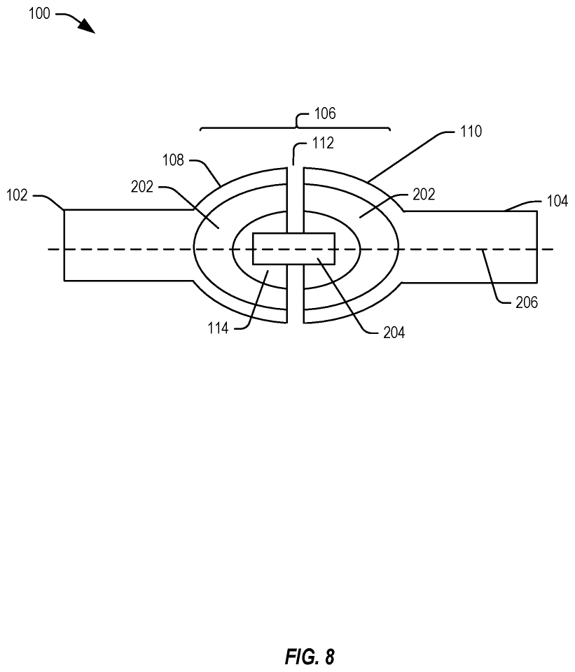

The cup 106 can include side walls 202 that have different configurations (see for example, FIGS. 6 and 7) depending on the desired light emission profiles.

FIG. 3 is a side view of the lead frame structure 100 of FIGS. 1 and 2 according to one or more embodiments of the present disclosure.

In the embodiment shown in FIG. 3, which is not drawn to scale, the leads 102 and 104's bottom portions 120 and 122 extend some distance below the top portions 116 and 118 (shown by the dashed lines). During fabrication of the LED package, the leads 102 and 104 can be joined together by a connecting portion 302 that holds the leads 102 and 104 in place to maintain the gap 112 when the LED device 204 is being mounted. After the molded lens has encapsulated the upper portions 116 and 118, and the LED device 204, the connecting portion 302 can be removed. The molded lens can then hold the leads 102 and 104 in place to maintain the gap 112 so that the leads 102 and 104 do not make electrical contact. The gap 112 can include air that insulates the leads 102 and 104. In other embodiments, the material that the molded lens is formed from (e.g., silicone) can infill into the gap 112.

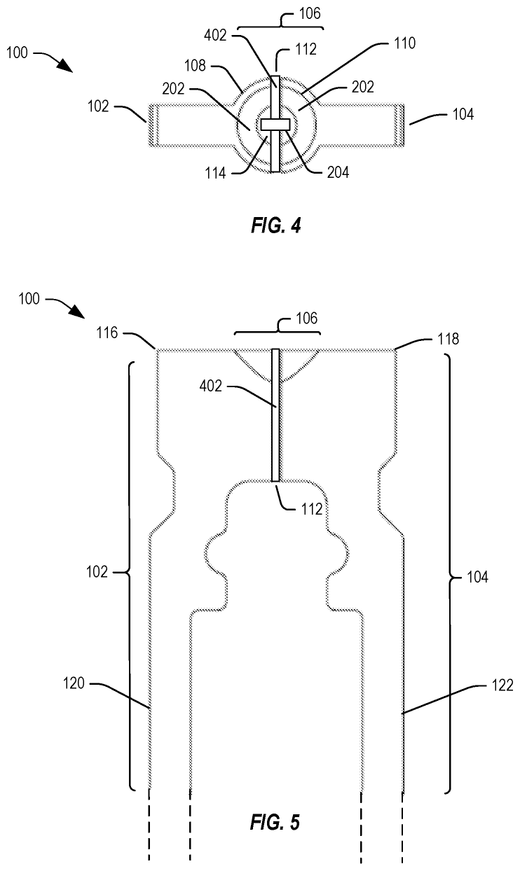

In the embodiment shown in FIGS. 2 and 3, there is no fill material (at least until the lens is formed). In the embodiments shown in FIGS. 4 and 5 however, a fill material 402 can be placed in between the leads 102 and 104. The fill material can make it simpler to align the leads 102 and 104 when placing the LED device 204, and can even include adhesives to bond to the leads 102 and 104 to stabilize the leads 102 and 104. The fill material 402 can provide thermal buffering and facilitate thermal dissipation. The fill material 402 can also be an electrical insulator. In an embodiment, the fill material 402 could be a light-altering material, such as one that is reflective or absorptive. In an embodiment, the fill material 402 could traverse across the top portions 116 and 118 of the leads 102 and 104 like a stripe, that extends in and up to fill in the gap 112.

FIG. 6 is a cross-sectional view of an LED device 204 mounted across a gap 112 between the split cup portions 108 and 110 of the pair of leads 102 and 104 with a first side wall configuration according to one or more embodiments of the present disclosure.

The side walls 202 in FIG. 6 can be angled with respect to a vertical axis 604. The side walls 202 can include one planar surface as shown in FIG. 6, or could potentially include multiple planar portions. The side walls 202 and bottom surface 114 may also optionally include a layer of light-altering material 606, either reflective or absorptive to further modify the light emission profile of the lead frame structure 100. The light-altering material 606 can be a coating applied during fabrication, or can be integral to the side wall 202.

The angle at which the side walls 202 are configured with respect to the axis 604 can also be modified based on the desired light emission profile. For example, larger angles could include a wider FFP, whereas smaller angles (e.g. more vertical sidewalls) could lead to a narrower FFP.

The LED device 204 can include contact pads 603 that electrically couple the LED device 204 to the bottom surface 114 via solder layers 602.

FIG. 7 is a cross-sectional view of an LED device 204 mounted across a gap 112 between the split cup portions 108 and 110 of the pair of leads 102 and 104 with a second side wall configuration according to one or more embodiments of the present disclosure.

In the embodiment in FIG. 7, the side walls 202 include a vertical wall portion 704 and a wall portion 702 that is angled with respect to the vertical wall portion 704. In certain embodiments, the vertical wall portion 704 may form a right angle with the bottom surface 114. The angle, like in the embodiment in FIG. 6 can be based on the desired light emission profile. Shown in FIG. 7 is an embodiment that can also be applicable to the embodiment in FIG. 6. Where the light-altering material 606 can also be applied to a top surface of the fill material 402 in the gap 112 as well as the bottom surface 114 of the cup 106.

FIG. 8 is a top-down view of the pair of leads of a lead frame structure 100 similar to that of FIG. 2 but with an oval cup 106 according to one or more embodiments of the present disclosure. As with the circular embodiments, above, the gap 112 may form a line of symmetry for the oval cup 106. The oval cup 106 can improve light emission along a plane parallel to the axis 206 relative to a lead frame structure 100 with a circular cup as shown in FIG. 2. In other embodiments, other shapes of cups are possible, depending on the desired light emission profiles. For example, in an embodiment, the bottom surface 114 of the cup can be circular, while the side walls 202 can form a cup with an oval shape.

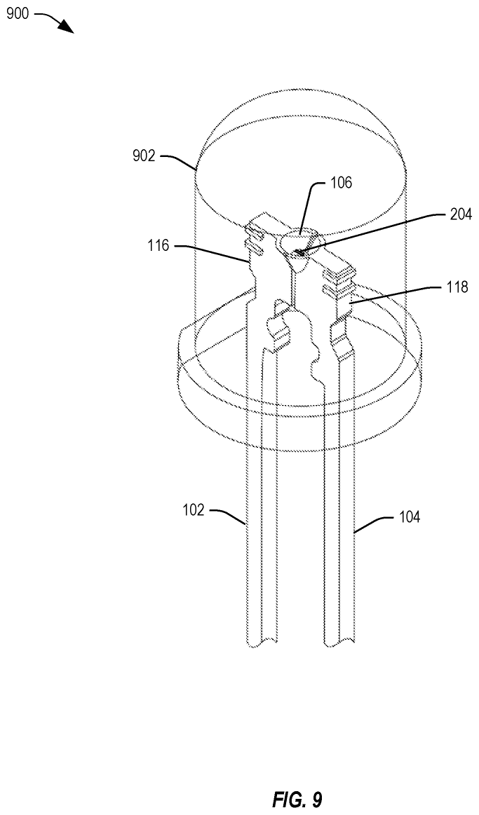

FIG. 9 is a side view of an LED package 900 that includes the lead frame structure 100 with the LED device 204 and a molded lens 902 according to one or more embodiments of the present disclosure. The molded lens 902 can further modify the light emission profile of the LED package 900, and also serve as an encapsulant, protective cover for the LED device 204 within the LED package 900. The molded lens 902 can be formed around the top portions 116 and 118 of the leads 102 and 104 respectively. In an embodiment, the molded lens can be silicone or an epoxy and can also keep the leads 102 and 104 separated so that the leads 102 and 104 do not touch, and are ensure they are otherwise aligned.

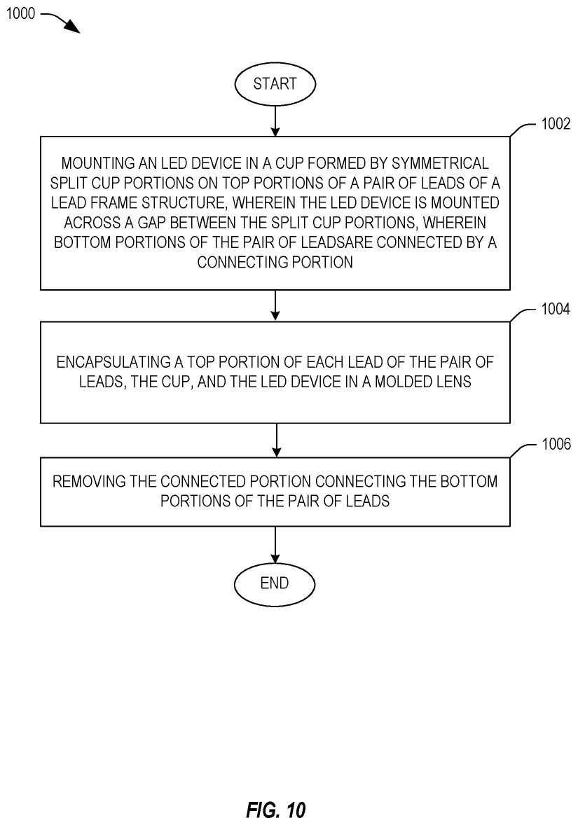

FIG. 10 is a flow chart of a method for making an LED package with a symmetrical lead frame structure according to one or more embodiments of the present disclosure.

In an embodiment, the method can begin at 1002 where the method includes mounting an LED device in a cup 106 formed by symmetrical split cup portions 108 and 110 on top portions of the pair of leads 102 and 104 of a lead frame structure 100, wherein the LED device 204 is mounted across a gap 112 between the split cup portions 108 and 110, wherein bottom portions 120 and 122 of a pair of leads 102 and 104 are connected by a connecting portion 302.

In an embodiment, the method could also include applying a layer of light-altering material 606 to the side walls 202 and bottom surface 114 of the split cup portions 108 and 110.

At 1004, the method includes encapsulating a top portion 116 and 118 of each lead 102 and 104 of the pair of leads, the cup 106, and the LED device 204 in a molded lens 902. The molded lens 902 can be silicone, epoxy or other suitable light-transmissive material.

At 1006, the method includes removing the connected portion (e.g., connected portion 302) connecting the bottom portions 120 and 122 of the pair of leads 102 and 104.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a lead frame structure, comprising a pair of leads that each comprise a respective split cup portion on a top portion of the lead, such that a cup is formed by split cup portions of the pair of leads when the pair of leads are adjacent to each other, wherein the cup comprises a gap between the split cup portions; and
an LED device mounted in the cup across the gap, wherein the LED device is electrically coupled to both split cup portions.

2. The LED package of claim 1, further comprising:
a molded lens that encapsulates a top portion of each lead of the pair of leads, the cup, and the LED device.

3. The LED package of claim 1, wherein the LED device is thermally coupled to both split cup portions.

4. The LED package of claim 1, wherein the split cup portions of the pair of leads that form the cup are symmetrical across a line of symmetry formed by the gap.

5. The LED package of claim 1, wherein the cup is circular.

6. The LED package of claim 1, wherein the cup is oval.

7. The LED package of claim 1, wherein a top portion of the cup forms an oval, and a bottom surface of the cup is circular.

8. The LED package of claim 1, wherein the split cup portions comprise respective bottom surfaces on which the LED device is mounted.

9. The LED package of claim 2, wherein material of the molded lens is in the gap between the split cup portions.

10. The LED package of claim 2, wherein top portions of the leads that are encapsulated in the molded lens are symmetrical.

11. The LED package of claim 1, further comprising:
a fill material in the gap between the split cup portions, wherein the fill material is an electrically insulating material.

12. The LED package of claim 9, wherein a top surface of the fill material has a reflective coating applied thereonto.

13. The LED package of claim 1, wherein surfaces of the split cup portions of the pair of leads have a reflective coating applied thereonto.

14. The LED package of claim 1, wherein side walls of the split cup portions comprise a surface that is angled with respect to a vertical axis of the pair of leads.

15. The LED package of claim 1, wherein sidewalls of the split cup portions comprise a vertical wall portion and a wall portion that is angled with respect to the vertical wall portion.

16. The LED package of claim 1, wherein the LED device is a flip-chip.

17. The LED package of claim 1, wherein the pair of leads are aligned along an axis, and wherein the LED device is mounted along the axis.

18. A light-emitting diode (LED) package comprising:
a lead frame structure comprising a pair of leads, wherein each of the leads comprise symmetrical split cup portions on a top portion of the lead, such that a cup is formed by the split cup portions of the pair of leads when the pair of leads are adjacent to each other, wherein the cup comprises a bottom surface and a gap between the split cup portions;
an LED device mounted in on the bottom surface of the split cup portions, wherein a first end of the LED device is mounted on a first bottom surface of a first split cup portion and a second end of the LED device is mounted on a second bottom surface of a second split cup portion; and
a molded lens that encapsulates a top portion of each leads of the pair of leads, the cup, and the LED device.

19. The LED package of claim 18, wherein material of the molded lens is in the gap between the split cup portions.

20. The LED package of claim 18, further comprising:
a fill material in the gap between the split cup portions, wherein the fill material is an electrical insulator.

21. The LED package of claim 18, wherein the pair of leads are aligned along an axis, and wherein the LED device is mounted along the axis.

22. A method for forming a light-emitting diode (LED) package:
mounting an LED device in a cup formed by symmetrical split cup portions on top portions of a pair of leads of a lead frame structure, wherein the LED device is mounted across a gap between the split cup portions, wherein bottom portions of the pair of leads are connected by a connecting portion;
encapsulating a top portion of each lead of the pair of leads, the cup, and the LED device in a molded lens; and
removing the connected portion connecting the bottom portions of the pair of leads.
